(19) United States
(12) Patent Application Publication
(10) Pub. No.: US 2023/0258507 A1
(43) Pub. Date: Aug. 17, 2023

(54) PROTECTED HIGH TEMPERATURE IRRADIATION RESISTANT THERMOCOUPLE

(71) Applicant: Battelle Energy Alliance, LLC, Idaho Falls, ID (US)

(72) Inventors: Richard S. SKIFTON, Idaho Falls, ID (US); Douglas A. CORBETT, Rigby, ID (US)

(21) Appl. No.: 18/109,193

(22) Filed: Feb. 13, 2023

Related U.S. Application Data
(60) Provisional application No. 63/309,582, filed on Feb. 13, 2022.

(51) Int. Cl. G01K 7/06; G01K 7/10

(52) U.S. Cl. CPC G01K 7/06; G01K 7/10

(57) ABSTRACT

A thermocouple may have a first thermoelement wire formed of a first material and a first sheath covering at least part of the first thermoelement wire. The first sheath may provide thermal insulation and may be formed of a third material, different from the first material, that is subject to oxidation in response to exposure to a surrounding material. The thermocouple may further have a second sheath covering at least a first portion of the first sheath. The second sheath may act as a barrier between the first portion of the first sheath and the surrounding material and may be formed of a fourth material that is resistant to oxidation in the surrounding material. The first thermoelement wire may be joined, at a junction, with one of the first sheath, and a second thermoelement wire formed of a second material different from the first material.

### CROSS REFERENCE TO RELATED APPLICATIONS

This application claims the benefit of U.S. Provisional Patent Application No. 63/309,582, filed on Feb. 13, 2022 and entitled PROTECTED HIGH TEMPERATURE IRRADIATION RESISTANT THERMOCOUPLE, the disclosure of which is incorporated as though set forth herein in its entirety.

### STATEMENT REGARDING FEDERALLY SPONSORED RESEARCH OR DEVELOPMENT

This invention was made with government support under Contract Number DE-AC07-05-ID14517 awarded by the United States Department of Energy. The government has certain rights in the invention.

### TECHNICAL FIELD

This disclosure relates to temperature measurement systems and methods. More specifically, this disclosure relates to thermocouples that are able to reliably measure high temperatures in irradiated and/or corrosive environments.

### BACKGROUND

The accurate measurement of temperatures between 1100° C. and 1700° C. is important to the safe, efficient and economical operation of many industries such as electrical power production, processing and refining of chemicals, the fabrication of steel and other metals, and production of glass and ceramic materials. Accurate temperature measurement over time can also facilitate the operation of industrial machinery such as jet engines, nuclear reactors, gasification units, incinerators, and gas turbines. In such temperature environments, thermocouples are the most widely used industrial temperature sensors because they are rugged, affordable, and accurate—at least initially.

Unfortunately, after installation, commercially-available thermocouples are generally unstable in this temperature range and prone to decalibration or “drift,” providing increasingly unreliable and unpredictable readings as they age. As operating temperatures and thermal cycles increase, the performance of these thermocouples decreases. Together, these factors often result in costly redundant instrument clusters, sensor failures, downtime and potential accidents due to undetected overheating. For temperatures above 1100° C. in high-radiation environments, such as in high-temperature nuclear test reactors, conventional thermocouples are generally incapable of stable and accurate operation. For these reasons, High-Temperature Irradiation-Resistant (“HTIR”) thermocouples have been developed. One example is set forth in U.S. Pat. No. 7,871,198, which is incorporated by reference as though set forth herein in its entirety.

One limitation of this HTIR technology is the limited environments in which HTIR thermocouples can be used. HTIR thermocouples can withstand high temperatures, multiple thermal cycling, and in-pile irradiation for extended periods of time without significant aging (drift) and/or transmutation to the thermoelements and other components of the TC. However, HTIR thermocouples must generally be kept in an inert atmosphere—greatly reducing the available market.

There is a need in the art for thermocouples that extend the benefits of HTIR technology to additional, non-inert and/or corrosive environments.

### SUMMARY

The various devices, systems, and/or methods of the present disclosure have been developed in response to the present state of the art, and in particular, in response to the problems and needs in the art that have not yet been fully solved by currently available technology.

In some embodiments, a thermocouple may have a first thermoelement wire formed of a first material and a first sheath covering at least part of the first thermoelement wire. The first sheath may provide thermal insulation and may be formed of a third material, different from the first material, that is subject to oxidation in response to exposure to a surrounding material. The thermocouple may further have a second sheath covering at least a first portion of the first sheath. The second sheath may act as a barrier between the first portion of the first sheath and the surrounding material and may be formed of a fourth material that is resistant to oxidation in the surrounding material. The first thermoelement wire may be joined, at a junction, with one of the first sheath, and a second thermoelement wire formed of a second material different from the first material.

The first portion of the first sheath may be a proximal end of the first sheath such that a distal end of the first sheath and the first thermoelement wire remain uncovered by the second sheath.

The thermocouple may be configured to be used to measure temperature in a high temperature environment adjacent to the surrounding material, with the distal end within the high temperature environment and the proximal end is positioned outside the high temperature environment and within the surrounding material.

The first sheath may be configured to withstand temperatures of at least 1250° C.

The thermocouple may further have a proximal seal that seals a proximal portion of the second sheath such that the second sheath and the proximal seal insulate the first sheath and the first thermoelement wire from the surrounding material.

The first sheath may have a first diameter. The second sheath may have a second diameter that is greater than the first diameter but less than two times the first diameter.

The second sheath may be formed of a material comprising Inconel.

The second sheath may be formed of a material selected from the group consisting of Hastelloy N, Hastelloy C, Hastelloy X, Pyrosil, 316 Stainless Steel, Nickel, and combinations thereof.

According to some embodiments, a method of forming a thermocouple may include joining a first thermoelement wire, at a junction, with one of a first sheath and a second thermoelement wire, and covering at least part of the first thermoelement wire with the first sheath. The first sheath may be configured to provide thermal insulation and is formed of a third material that is subject to oxidation in response to exposure to a surrounding material. The method may further include covering at least a first portion of the first sheath with a second sheath configured to act as a barrier between the first portion of the first sheath and the surrounding material. The second sheath may be formed of a fourth material that is resistant to oxidation in the surrounding material.

Covering at least part of the first thermoelement wire with the first sheath may include forming a seal, with the first sheath, around the first thermoelement wire.

Covering at least part of the first thermoelement wire with the first sheath may include swaging the first sheath around the first thermoelement wire, and heat treating the first sheath and the first thermoelement wire.

The method may further include, prior to swaging the first sheath around the first thermoelement wire, Inserting the first thermoelement wire into the first sheath, and covering the first sheath with a foil.

Heat treating the first sheath and the first thermoelement wire may include heat treating the first sheath and the first thermoelement wire at a temperature between 1400° C. and 1800° C.

The method may further include, prior to covering at least the first portion of the first sheath with the second sheath, removing Oxygen from the first sheath.

Covering at least the first portion of the first sheath with the second sheath may include forming a seal, with the second sheath, around the first portion of the first sheath.

Covering at least the first portion of the first sheath with the second sheath may include, with the second sheath formed as a tube, Inserting the first portion of the first sheath into the tube, and swaging the second sheath around the first sheath.

According to some embodiments, a method of sensing temperature, in a high temperature environment adjacent to surrounding material of a corrosive nature, may include positioning a thermocouple near the high temperature environment. The thermocouple may include a first thermoelement wire formed of a first material, and a first sheath covering at least a distal end of the first thermoelement wire. The first sheath may be formed of a third material, different from the first material, that is subject to oxidation in response to exposure to a surrounding material. The thermocouple may further include a second sheath covering a proximal end of the first thermoelement wire and the first sheath. The second sheath may be formed of a fourth material that is resistant to oxidation in the surrounding material. The first thermoelement wire may be joined, at a junction, with one of the first sheath, and a second thermoelement wire formed of a second material different from the first material. The method may further include inserting the distal end into the high temperature environment such that the proximal end of the thermocouple is positioned outside the high temperature environment and within the surrounding material, such that first sheath provides thermal insulation sufficient to withstand the high temperature environment and the second sheath acts as a barrier between the proximal end and the surrounding material.

The distal end may be uncovered by the second sheath such that inserting the distal end into the high temperature environment includes avoiding insertion of the second sheath into the high temperature environment.

The second sheath may be formed of a material comprising Inconel.

The high temperature environment may be an interior of a fuel pin for nuclear power U generation. The surrounding material may include water, liquid metal, and/or molten salt.

### BRIEF DESCRIPTION OF THE DRAWINGS

Exemplary embodiments of the disclosure will become more fully apparent from the following description and appended claims, taken in conjunction with the accompanying drawings. Understanding that these drawings depict only exemplary embodiments and are, therefore, not to be considered limiting of the scope of the appended claims, the exemplary embodiments of the present disclosure will be described with additional specificity and detail through use of the accompanying drawings in which:

FIG. 1 is a perspective view of a thermocouple according to one embodiment of the present disclosure;

FIG. 2 is a conceptual section view of the thermocouple of FIG. 1;

FIG. 3 is a flowchart depicting a method of manufacturing a thermocouple, according to one embodiment; and

FIG. 4 is a conceptual section view of a thermocouple according to one alternative embodiment.

It is to be understood that the drawings are for purposes of illustrating the concepts of the disclosure and may not be drawn to scale. Furthermore, the drawings illustrate exemplary embodiments and do not represent limitations to the scope of the present disclosure.

### DETAILED DESCRIPTION

Exemplary embodiments of the present disclosure will be best understood by reference to the drawings, wherein like parts are designated by like numerals throughout. It will be readily understood that the components of the present disclosure, as generally described and illustrated in the drawings herein, could be arranged and designed in a wide variety of different configurations. Thus, the following more detailed description of the embodiments of the apparatus and method, as represented in the drawings, is not intended to limit the scope of the present disclosure, as claimed in this or any other application claiming priority to this application, but is merely representative of exemplary embodiments of the present disclosure.

The phrases “connected to,” “coupled to” and “in communication with” refer to any form of interaction between two or more entities, including mechanical, electrical, magnetic, electromagnetic, fluid, and thermal interaction. Two components may be functionally coupled to each other even though they are not in direct contact with each other. The term “abutting” refers to items that are in direct physical contact with each other, although the items may not necessarily be attached together. The phrase “fluid communication” refers to two features that are connected such that a fluid within one feature is able to pass into the other feature.

The word “exemplary” is used herein to mean “serving as an example, instance, or illustration.” Any embodiment described herein as “exemplary” is not necessarily to be construed as preferred or advantageous over other embodiments. While the various aspects of the embodiments are presented in drawings, the drawings are not necessarily drawn to scale unless specifically indicated.

The present disclosure discloses a Protected High-Temperature Irradiation-Resistant (“PHTIR”) thermocouple that may be capable of measuring extremely high temperatures (>1250° C.) in aqueous, caustic, liquid metal, and/or molten salt environments. This PHTIR technology may retain the benefits of HTIR thermocouples, namely, high-temperature measurement with low drift in irradiated environments. Thus, the PHTIR technology may enable these benefits to be extended to non-inert environments such as measurement of the in-pile temperature of a fuel centerline. The PHTIR thermocouple may have a double-walled sheath over the thermocouple thermoelements. A selection of different metal tubes can be utilized as the outer sheath to fit the needs of the sensing environment. The proper overall dimensions (i.e., outer and inner diameter and length) before and after thermocouple construction may be used to avoid thermocouple shunting, splitting, cracking, etc. These features and benefits will be set forth in greater detail below.

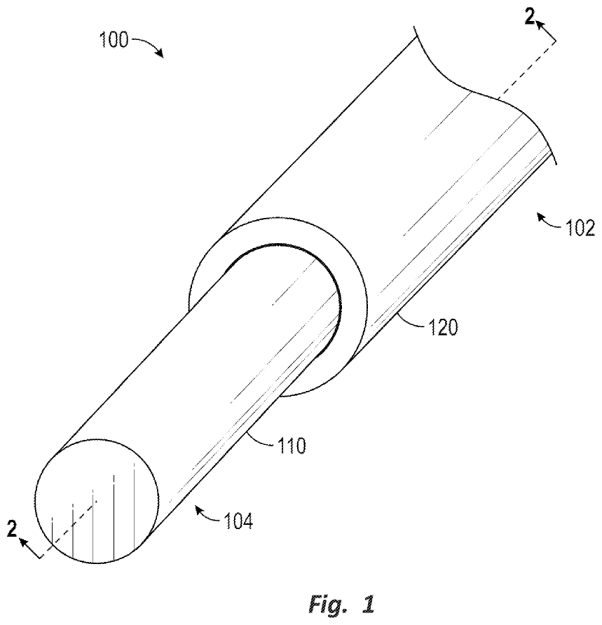

Referring to FIG. 1, a perspective view is shown of a thermocouple 100 according to one embodiment. The thermocouple 100 may be used to measure temperature in uniquely demanding environments, such as the interior of a fuel rod of a nuclear reactor. Thus, the thermocouple 100 may advantageously be designed to withstand high temperatures (for example, over 1250° C.), and may further be resistant to radiation and/or corrosion. In this application, “withstanding” an environment means that the thermocouple remains functional for several (for example, at least ten) operational cycles in the environment. In some embodiments, the thermocouple 100 may be designed to withstand a maximum temperature in the range of 1250° C. to 1800° C. More specifically, the thermocouple 100 may be designed to withstand a maximum temperature in the range of 1350° C. to 1700° C. Yet more specifically, the thermocouple 100 may be designed to withstand a maximum temperature in the range of 1450° C. to 1600° C. Yet more specifically, the thermocouple 100 may be designed to withstand a maximum temperature of 1550° C.

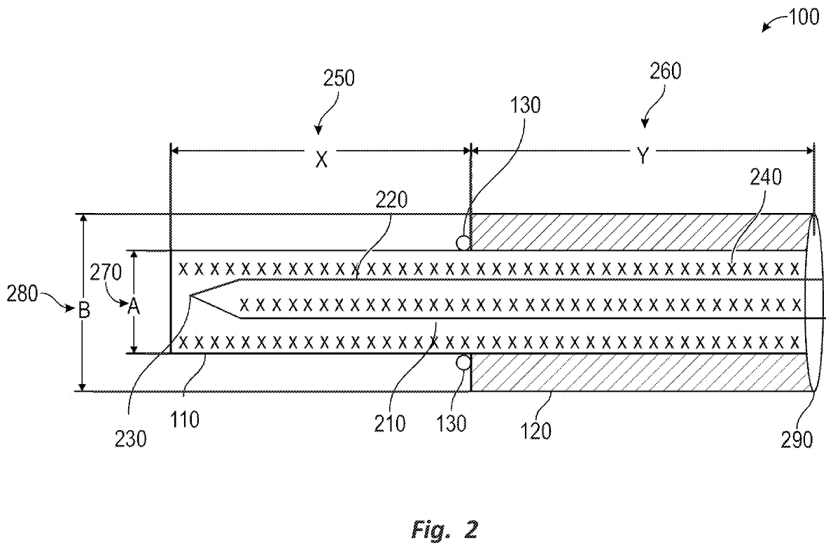

The thermocouple 100 may have a proximal end 102 and a distal end 104. The thermocouple 100 may have thermoelement wires (shown in FIG. 2) that are encased in a first sheath 110 and a second sheath 120. The first sheath 110 may provide insulation against the high temperatures to which the thermocouple 100 may be exposed, and may optionally cover the thermoelement wires in their entirety. The second sheath 120 may protect part of the first sheath 110 (and thus, the thermoelement wires) from surrounding corrosive material such as water, liquid metal, and/or molten salt. In this application, a “sheath” refers to any structure that is designed to cover another structure to provide mechanical, thermal, radiological, fluidic, and/or other insulation.

As shown, the second sheath 120 may optionally cover only part of the first sheath 110. For example, the second sheath 120 may be of a length that covers the proximal end 102 of the thermocouple 100, but not the distal end 104 of the thermocouple 100. This is because the distal end 104 may optionally be inserted into an inert environment, such as the interior of a nuclear reactor fuel pin. The proximal end 102 may remain outside the fuel pin, exposed to the corrosive material surrounding the fuel pin. Thus, the second sheath 120 need not necessarily cover the distal end 104. In some embodiments, the distal end 104 may be exposed to higher temperatures (for example, greater than 1250° C.) than the proximal end 102, which may only be exposed to temperatures lower than 1250° C. The partial coverage of the second sheath 120 may allow a material to be used for the second sheath 120 that would not withstand the temperatures present at the distal end 104, but would withstand those present at the proximal end 102.

In alternative embodiments (not shown), the second sheath 120 may be made to cover the entirety of the first sheath 110. This may be beneficial when the temperature at the distal end 104 does not exceed the material limits of the second sheath 120 and/or the distal end 104 is also expired to the corrosive material.

In further alternative embodiments (not shown), the second sheath 120 may cover the entire working length of the thermoelectric wires, from the proximal end 102 to the distal end 104, and the first sheath 110 may be omitted entirely. This may be a suitable configuration, for example, for environments that are corrosive, but low enough in temperature that they do not exceed the temperature limits of the second sheath 120.

FIG. 2 is a conceptual section view of the thermocouple 100 of FIG. 1, taken along the plane labeled “2-2” in FIG. 1. As shown, the thermocouple 100 may have a first thermoelement wire 210 and a second thermoelement wire 220 that are joined together at a junction 230 at the distal end 104 of the thermocouple 100. The first thermoelement wire 210 and the second thermoelement wire 220 may be made of different materials selected such that a detectable Voltage is produced in response to temperature change at the junction 230. This change is called the “Seebeck Effect.”

The first thermoelement wire 210 and the second thermoelement wire 220 may optionally be encased in an insulator 240 that insulates the first thermoelement wire 210 from the second thermoelement wire 220, except at the junction 230. The insulator 240 may generally encase and contain the first thermoelement wire 210, the second thermoelement wire 220, and the junction 230. The insulator 240 may, in turn, be encased within the first sheath 110. As described previously, the second sheath 120 may cover at least part of the first sheath 110.

At the proximal end 102, the first thermoelement wire 210 and the second thermoelement wire 220 may extend proximally out of the first sheath 110. A seal 290 may be used to keep extraneous material out of the first sheath 110 and maintain the integrity of the first thermoelement wire 210, the second thermoelement wire 220, and the insulator 240.

The components of FIG. 2 may be formed of any materials known in the art of thermocouple design. In some examples, the first thermoelement wire 210 and the second thermoelement wire 220 may both be formed of refractory metals that are validated to have high melting temperatures and relatively low neutron absorption cross sections. For example, the first thermoelement wire 210 may be formed of Niobium and the second thermoelement wire 220 may be formed of Molybdenum. The insulator 240 may be formed of a metal oxide such as Magnesium Oxide (MgO), Aluminum Oxide (Al₂O₃), or the like. The first sheath 110 may be made of Niobium or a similar material. The second sheath 120 may be made of Inconel 6xx (for example, Inconel 600), Inconel 7xx (for example, Inconel 700), or a similar material. Additionally or alternatively, the second sheath 120 may be formed of Hastelloy N, Hastelloy C, or Hastelloy X (in particular for a molten salt reactor), Pyrosil, 316 Stainless Steel, Nickel, and/or other exotic alloys. The seal 290 may be made of an epoxy and/or any other material that seals against the second sheath 120 to avoid contamination from the surrounding material.

FIG. 2 also shows some exemplary dimensions. For example, an X dimension 250 may be the length of the distal end 104, from the end of the second sheath 120 to the distal tip of the thermocouple 100. A Y dimension 260 may be the length of the second sheath 120. An A dimension 270 may be the width of the first sheath 110, and a B dimension 280 may be the width of the second sheath 120.

In some embodiments, the X dimension 250 may equal to or slightly less than the depth of penetration of the distal end 104 into an inert environment, such as the interior of the fuel pin mentioned previously. The Y dimension 260 may be equal to or slightly greater than the length of the thermocouple 100 that is to be exposed to caustic material.

In some embodiments, the X dimension 250 may be 0, where the second sheath 120 is to extend along the entirety of the distal end 104 of the thermocouple 100, as described previously. This may be appropriate where the full length of the thermocouple 100 is surrounded by caustic material, but the temperatures experienced at the proximal end 102 and the distal end 104 do not exceed the material limits of the second sheath 120.

In alternative embodiments, the Y dimension 260 may be 0, indicating that the second sheath 120 is not present at all. This may be appropriate where the thermocouple 100 will not be exposed to caustic material but will experience higher temperatures. This configuration may be similar to that of U.S. Pat. No. 7,871,198 (the HTIR described previously).

Thus, the X dimension 250 and the Y dimension 260 may be adapted to the specific environment in which the thermocouple 100 is to be used. Some tradeoffs may be made between high temperature tolerance and corrosion resistance.

The A dimension 270 may, for example, be within the range of 0.025 inches to 0.2 inches. Further, the A dimension 270 may be within the range of 0.075 inches to 0.125 inches. Yet further, the dimension 270 may be within the range of 0.09 inches to 0.11 inches. Yet further, the dimension 270 may be about 0.1 inches.

The B dimension 280 may be determined based on the A dimension 270. For example, the B dimension 280 may be within the range of one times the A dimension 270 to two times the A dimension 270. Further, the B dimension 280 may be within the range of 1.1 times the A dimension 270 to 1.5 times the A dimension 270. Yet further, the B dimension 280 may be within the range of 1.2 times the A dimension 270 to 1.4 times the A dimension 270. Still further, the B dimension 280 may be about 1.25 times the A dimension 270.

These material selections and dimensions are merely exemplary. Those of skill in the art will recognize that many variations of the foregoing may be used. Any other materials or a dimensions known in the art of thermocouple design may be applied to the thermocouple 100, including but not limited to those set forth in U.S. Pat. No. 7,871,198.

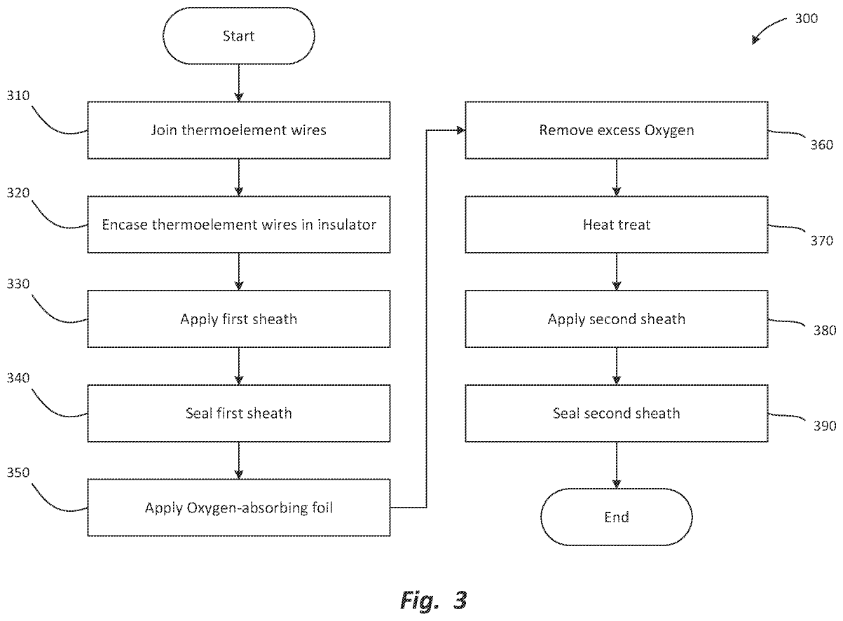

FIG. 3 is a flowchart of a method 300 of making a thermocouple, such as the thermocouple 100 of FIGS. 1 and 2, according to one embodiment. The method 300 is not limited to the thermocouple 100, and likewise, the thermocouple 100 and those of alternative embodiments set forth above may be made according to other methods besides the method 300.

In a step 310, the first thermoelement wire 210 and the second thermoelement wire 220 may be joined together at the junction 230. If desired, the ends of the first thermoelement wire 210 and the second thermoelement wire 220 may be mechanically joined, brazed, chemically bonded, or otherwise secured together to form the junction 230.

In a step 320, the first thermoelement wire 210 and the second thermoelement wire 220, including the junction 230, may be encased in the insulator 240. The insulator 240 may be insert molded around, wrapped around, and/or otherwise formed such that it maintains electrical separation between the first thermoelement wire 210 and the second thermoelement wire 220, except at the junction 230.

In a step 330, the first sheath 110 may be applied to the first thermoelement wire 210, the second thermoelement wire 220, and the insulator 240. According to some examples, the first sheath 110 may be applied as a tube around the insulator 240 and then swaged on to the insulator 240 so that the first sheath 110 fills any voids present in the insulator 240. The first sheath 110 may be designed to form a gastight seal around the first thermoelement wire 210, the second thermoelement wire 220, and the insulator 240.

In a step 340, the first sheath 110 may be sealed over the first thermoelement wire 210, the second thermoelement wire 220, and the insulator 240 (or at least the portions thereof that are to be disposed in high-temperature and/or caustic environments). In some embodiments, the swaging process mentioned above may accomplish sealing. In alternative embodiments, and epoxy seal or other sealing mechanism may be applied to the first sheath 110 to seal the first sheath 110 around the first thermoelement wire 210, the second thermoelement wire 220, and the insulator 240.

In a step 350, the first thermoelement wire 210, the second thermoelement wire 220, the insulator 240, and the first sheath 110 may be wrapped in a Niobium foil in preparation for excess Oxygen removal and/or heat-treating. The Niobium foil may be applied such that another seal is formed around the first sheath 110. In addition to or in the alternative to the Niobium foil, other materials such as a Tantalum or Titanium foil may be used to cover the first sheath 110.

In a step 360, excess Oxygen may be removed from the thermocouple 100, and in particular, from the first sheath 110. The Niobium foil may facilitate this process by leeching or otherwise removing Oxygen from the first sheath 110. In some embodiments, this may be done at high temperatures, for example, during the subsequent heat-treating process. Additionally or alternatively, the thermocouple 100 may pass through a gettering furnace in which Argon or another noble gas receives the excess Oxygen, and the Oxygen is removed from the gas.

In a step 370, the first thermoelement wire 210, the second thermoelement wire 220, the insulator 240, the first sheath 110, and the Niobium (or other) foil may be heat-treated. It may be advantageous to heat-treat the first thermoelement wire 210, the second thermoelement wire 220, the insulator 240, and the first sheath 110 after the swaging process in order to relieve material strain induced by the swaging process. This may be done before, during, and/or after removal of the excess Oxygen in the step 360. The heat-treating stage may help to relieve such stresses and reduce the brittleness of the thermocouple 100. Further, the heat treatment process may help to dampen any EMF degradation during use of the thermocouple 100.

In some embodiments, heat-treating may be carried out at temperatures higher than are generally expected to be experienced in the operating life of the thermocouple 100. In some examples, heat-treating may be carried out within the range of 1,400° C. to 1,800° C. More specifically, heat-treating may be carried out within the range of 1,500° C. to 1,700° C. Yet more specifically, heat-treating may be carried out at about 1,600° C.

In a step 380, the second sheath 120 may be applied to the first thermoelement wire 210, the second thermoelement wire 220, the insulator 240, and the first sheath 110. According to some examples, the second sheath 120 may be applied as a tube around at least a portion of the first sheath 110 and then swaged on to the first sheath 110. The second sheath 120 may be designed to form a gastight seal around the portion of the first sheath 110 to which it is applied. Additionally or alternatively, the second sheath 120 may be applied by chemical vapor deposition to form a thin coat barrier between the first sheath 110 and the working environment.

In some embodiments, the thermocouple 100 may again be heat-treated to remove strains in the thermocouple 100 induced by the swaging process. This may again improve ductility and reduce brittleness to help increase the operating life and resilience of the thermocouple 100. This step is optional and may not be needed in all circumstances.

In a step 390, a seal may be formed between first sheath 110 and second sheath 120, if needed. This is shown as seal weld 130 in FIG. 2. This may be done by a high temperature laser weld, braze, or the like. Additionally or alternatively, the seal 290 may be applied to the proximal end of the second sheath 120 to seal the proximal end 102 of the thermocouple 100. This may be done by applying a high-temperature epoxy or the like.

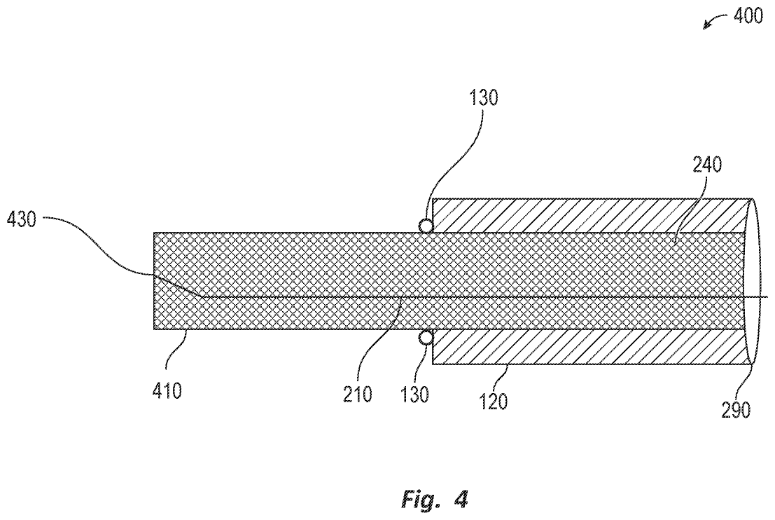

FIG. 4 is a conceptual section view of a thermocouple 400 according to one alternative embodiment. As shown, the thermocouple 400 may have a first thermoelement wire 210, a first sheath 410, and a second sheath 120. The first sheath 410 and the second sheath 120 may generally function as described in connection with FIGS. 1-3. However, in place of the second thermoelement wire 220, the first thermoelement wire 210 may be joined, at a junction 430, directly with the distal end of the first sheath 410 so that the first sheath acts as the second thermoelement in the thermocouple. 400. The proximal ends of the first thermoelement wire 210 and the first sheath 410 may be electrically connected to a sensing circuit to indicate the temperature experienced by the thermocouple 400, at or near the junction 430.

The first thermoelement wire 210 may optionally be encased in an insulator 240 that insulates the first thermoelement wire 210 from the first sheath 410, except at the junction 430. The insulator 240 may generally encase and contain the first thermoelement wire 210 and the junction 430. The insulator 240 may, in turn, be encased within the first sheath 410. As in the previous embodiment, the second sheath 120 may cover at least part of the first sheath 410. A seal 290 may be used to keep extraneous material out of the first sheath 410 and maintain the integrity of the first thermoelement wire 210 and the insulator 240.

Any methods disclosed herein comprise one or more steps or actions for performing a the described method. The method steps and/or actions may be interchanged with one another. In other words, unless a specific order of steps or actions is required for proper operation of the embodiment, the order and/or use of specific steps and/or actions may be modified. Further, steps may be omitted, replaced with other steps, and/or supplemented with additional steps not specifically described, as would be envisioned by a person of skill in the art with the aid of the present disclosure.

Reference throughout this specification to “an embodiment” or “the embodiment” means that a particular feature, structure or characteristic described in connection with that embodiment is included in at least one embodiment. Thus, the quoted phrases, or variations thereof, as recited throughout this specification are not necessarily all referring to the same embodiment.

Similarly, it should be appreciated that in the above description of embodiments, various features are sometimes grouped together in a single embodiment, Figure, or description thereof for the purpose of streamlining the disclosure. This method of disclosure, however, is not to be interpreted as reflecting an intention that any claim require more features than those expressly recited in that claim. Rather, as the following claims reflect, inventive aspects lie in a combination of fewer than all features of any single foregoing disclosed embodiment. Thus, the claims following this Detailed Description are hereby expressly incorporated into this Detailed Description, with each claim standing on its own as a separate embodiment. This disclosure includes all permutations of the independent claims with their dependent claims.

Recitation in the claims of the term “first” with respect to a feature or element does not necessarily imply the existence of a second or additional such feature or element. Elements recited in means-plus-function format are intended to be construed in accordance with 35 U.S.C. § 112 Para. 6. It will be apparent to those having skill in the art that changes may be made to the details of the above-described embodiments without departing from the underlying principles set forth herein.

While specific embodiments and applications of the present disclosure have been illustrated and described, it is to be understood that the scope of this disclosure is not limited to a the precise configuration and components disclosed herein. Various modifications, changes, and variations which will be apparent to those skilled in the art may be made in the arrangement, operation, and details of the methods and systems of the present disclosure set forth herein without departing from it spirit and scope.

What is claimed is:

1. A thermocouple comprising:
a first thermoelement wire formed of a first material;
a first sheath covering at least part of the first thermoelement wire, wherein the first sheath is configured to provide thermal insulation and is formed of a third material, different from the first material, that is subject to oxidation in response to exposure to a surrounding material; and
a second sheath covering at least a first portion of the first sheath, wherein the second sheath is configured to act as a barrier between the first portion of the first sheath and the surrounding material and is formed of a fourth material that is resistant to oxidation in the surrounding material;
wherein the first thermoelement wire is joined, at a junction, with one of the first sheath, and a second thermoelement wire formed of a second material different from the first material.

2. The thermocouple of claim 1, wherein the first portion of the first sheath comprises a proximal end of the first sheath such that a distal end of the first sheath and the first thermoelement wire remain uncovered by the second sheath.

3. The thermocouple of claim 2, wherein the thermocouple is configured to be used to measure temperature in a high temperature environment adjacent to the surrounding material, with the distal end within the high temperature environment and the proximal end is positioned outside the high temperature environment and within the surrounding material.

4. The thermocouple of claim 2, wherein the first sheath is configured to withstand temperatures of at least 1250° C.

5. The thermocouple of claim 1, further comprising a proximal seal that seals a proximal portion of the second sheath such that the second sheath and the proximal seal insulate the first sheath and the first thermoelement wire from the surrounding material.

6. The thermocouple of claim 1, wherein:
the first sheath has a first diameter; and
the second sheath has a second diameter that is greater than the first diameter but less than two times the first diameter.

7. The thermocouple of claim 1, wherein the second sheath is formed of a material comprising Inconel.

8. The thermocouple of claim 1, wherein the second sheath is formed of a material selected from the group consisting of:
Hastelloy N;
Hastelloy C;
Hastelloy X;
Pyrosil;
316 Stainless Steel;
Nickel; and
combinations thereof.

9. A method of forming a thermocouple, the method comprising:
joining a first thermoelement wire, at a junction, with one of a first sheath and a second thermoelement wire;
covering at least part of the first thermoelement wire with the first sheath, wherein the first sheath is configured to provide thermal insulation and is formed of a third material that is subject to oxidation in response to exposure to a surrounding material; and
covering at least a first portion of the first sheath with a second sheath configured to act as a barrier between the first portion of the first sheath and the surrounding material and is formed of a fourth material that is resistant to oxidation in the surrounding material.

10. The method of claim 9, wherein covering at least part of the first thermoelement wire with the first sheath comprises forming a seal, with the first sheath, around the first thermoelement wire.

11. The method of claim 10, wherein covering at least part of the first thermoelement wire with the first sheath comprises:
swaging the first sheath around the first thermoelement wire; and
heat treating the first sheath and the first thermoelement wire.

12. The method of claim 11, further comprising:
prior to swaging the first sheath around the first thermoelement wire, Inserting the first thermoelement wire into the first sheath; and
covering the first sheath with a foil.

13. The method of claim 11, wherein heat treating the first sheath and the first thermoelement wire comprises heat treating the first sheath and the first thermoelement wire at a temperature between 1400° C. and 1800° C.

14. The method of claim 11, further comprising, prior to covering at least the first portion of the first sheath with the second sheath, removing Oxygen from the first sheath.

15. The method of claim 9, wherein covering at least the first portion of the first sheath with the second sheath comprises forming a seal, with the second sheath, around the first portion of the first sheath.

16. The method of claim 15, wherein covering at least the first portion of the first sheath with the second sheath comprises:
with the second sheath formed as a tube, Inserting the first portion of the first sheath into the tube; and
swaging the second sheath around the first sheath.

17. A method of sensing temperature, in a high temperature environment adjacent to surrounding material of a corrosive nature, the method comprising:
positioning a thermocouple near the high temperature environment, the thermocouple comprising:
a first thermoelement wire formed of a first material;
a first sheath covering at least a distal end of the first thermoelement wire, wherein the first sheath is formed of a third material, different from the first material, that is subject to oxidation in response to exposure to a surrounding material; and
a second sheath covering a proximal end of the first thermoelement wire and the first sheath, wherein the second sheath is formed of a fourth material that is resistant to oxidation in the surrounding material;
wherein the first thermoelement wire is joined, at a junction, with one of the first sheath, and a second thermoelement wire formed of a second material different from the first material; and
inserting the distal end into the high temperature environment such that the proximal end of the thermocouple is positioned outside the high temperature environment and within the surrounding material, such that first sheath provides thermal insulation sufficient to withstand the high temperature environment and the second sheath acts as a barrier between the proximal end and the surrounding material.

18. The method of claim 17, wherein the distal end is uncovered by the second sheath such that inserting the distal end into the high temperature environment comprises avoiding insertion of the second sheath into the high temperature environment.

19. The method of claim 17, wherein the second sheath is formed of a material comprising Inconel.

20. The method of claim 17, wherein:
the high temperature environment comprises an interior of a fuel pin for nuclear power generation; and
the surrounding material comprises water, liquid metal, and/or molten salt.
